(19) United States
(12) Patent Application Publication
(10) Pub. No.: US 2015/0044447 A1
(43) Pub. Date: Feb. 12, 2015

(54) CLEAVING THIN LAYER FROM BULK MATERIAL AND APPARATUS INCLUDING CLEAVED THIN LAYER

(71) Applicant: SILICON GENESIS CORPORATION, San Jose, CA (US)

(72) Inventor: Francois J. HENLEY, Aptos, CA (US)

(21) Appl. No.: 14/523,368

(22) Filed: Oct. 24, 2014

Related U.S. Application Data
(63) Continuation-in-part of application No. 13/766,522, filed on Feb. 13, 2013.
(60) Provisional application No. 61/598,283, filed on Feb. 13, 2012.

(51) Int. Cl. C30B 29/20; C30B 29/64; H04M 1/02

(52) U.S. Cl. CPC C30B 29/20; H04M 1/0202; C30B 29/64
USPC 428/220; 455/566; 264/430; 264/1.21; 156/256; 156/230; 428/334

(57) ABSTRACT

Embodiments relate to use of a particle accelerator beam to form thin layers of material from a bulk substrate. In particular embodiments, a bulk substrate (e.g. donor substrate) having a top surface is exposed to a beam of accelerated particles. In certain embodiments, this bulk substrate may comprise a core of crystalline sapphire (Al₂O₃) material. Then, a thin layer of the material is separated from the bulk substrate by performing a controlled cleaving process along a cleave region formed by particles implanted from the beam. Embodiments may find particular use as hard, scratch-resistant covers for personal electric device displays such as mobile phones or tablets, or as optical surfaces for fingerprint, eye, or other biometric scanning.

### CROSS-REFERENCES TO RELATED APPLICATIONS

This application is a continuation-in-part application of U.S. patent application Ser. No. 13/766,522, filed Feb. 13, 2013, which claims priority to U.S. Provisional Application No. 61/598,283, filed Feb. 13, 2012, all of which are commonly owned and incorporated by reference herein for all purposes.

### BACKGROUND OF THE INVENTION

Embodiments of the present invention relate generally to techniques including methods and apparatuses for forming layers from a bulk material. Certain embodiments may employ an accelerator process for the manufacture of films in a variety of applications calling for a hard, scratch-resistant surface exhibiting transparency to incident light, including but not limited to camera lens covers, personal electric device display covers, and fingerprint or eye biometric scan optical surfaces. But it will be recognized that the invention has a wider range of applicability; it can also be applied to opto-electronic devices such as light emitting diodes (LEDs) and semiconductor lasers, three-dimensional packaging of integrated semiconductor devices, photonic or photovoltaic devices, piezoelectronic devices, flat panel displays, microelectromechanical systems (“MEMS”), nano-technology structures, sensors, actuators, integrated circuits, biological and biomedical devices, and the like. It can also be used as a protective laminate offering protection in harsh chemical and temperature environments.

Certain embodiments may include methods and apparatuses for cleaving films from material in bulk form, such as sapphire, silicon carbide (SiC) or GaN ingots or cores. Conventionally, such films can be manufactured by techniques involving the sawing of bulk material. One example of sawing involves the use of a wire (“wiresaw”).

However, such materials suffer from material losses during conventional saw manufacturing called “kerf loss”, where the sawing process eliminates as much as 40% and even up to 60% of the starting material in singulating the material from a core or boule into an individual layer. This is an inefficient method of preparing films from expensive starting materials. The brittle and hard nature of many of these materials makes the manufacture of large area thin layers particularly challenging.

From the above, it is seen that techniques for forming suitable substrate materials of high quality and low cost are highly desired. Cost-effective and efficient techniques for the manufacture of hard, scratch-resistant films are also desirable.

### BRIEF SUMMARY OF THE INVENTION

Embodiments relate to use of a particle accelerator beam to form thin layers of material from a bulk substrate. In particular embodiments, a bulk substrate (e.g. donor substrate) having a top surface is exposed to a beam of accelerated particles. In certain embodiments, this bulk substrate may comprise a core of crystalline sapphire (Al₂O₃) material. Then, a thin layer of the material is separated from the bulk substrate by performing a controlled cleaving process along a cleave region formed by particles implanted from the beam. Embodiments may find particular use as hard, scratch-resistant covers for personal electric device displays such as mobile phones or tablets, or as optical surfaces for fingerprint, eye, or other biometric scanning.

### BRIEF DESCRIPTION OF THE DRAWINGS

FIG. 1 is a simplified process flow illustrating an embodiment of a method.

FIG. 2A shows a photo of a 20 μm thick silicon wafer formed according to an embodiment.

FIG. 2B shows a photo of a 50 μm thick silicon wafer formed according to an embodiment.

FIG. 3 shows a sapphire laminated optical window according to an embodiment.

FIG. 4 shows a cleave range for sapphire according to an embodiment.

FIG. 5 is a table showing estimated cost of cleaving as a function of a diameter of a sapphire core.

FIG. 6 shows a simplified view of an embodiment of a rig 600 for processing sapphire.

FIG. 7 is a simplified diagram illustrating a smart phone according to an embodiment of the present invention.

FIG. 8 is a simplified system diagram with a smart phone according to an embodiment of the present invention.

FIG. 9 is a simplified diagram of a smart phone system diagram according to an embodiment of the present invention.

### DETAILED DESCRIPTION OF THE INVENTION

According to embodiments of the present invention, techniques including a method for forming substrates are provided. More particularly, embodiments according to the present invention provide a method to form a layer of hard, scratch-resistant layer from a bulk material. In a specific embodiment, the layer of material is provided using a plurality of high energy particles to cause a formation of a cleave plane in the semiconductor substrate. Methods according to embodiments of the invention can be used in a variety of applications, including but not limited to transparent coverings for optical displays, fingerprint or eye biometric scan optical surfaces, optoelectronic devices, semiconductor device packaging, photovoltaic cells, MEMS devices, and others.

According to certain embodiments, beam-induced cleave technology may be used for the preparation of thin sapphire laminated windows. According to particular embodiments, a 20 μm sapphire laminate (c-cut or a-cut) may be bonded to a suitable optical blank. Examples of such optical blanks include but are not limited to, polymers, glass, or quartz. If two-sided sapphire is appropriate, a second sapphire laminate can be bonded to the backside of the blank.

An objective is to substitute a potentially more efficient and cost-effective kerfless wafering technology than current wiresawing approaches. Single crystal sapphire core diameters of 2″, 3″, 4″, 6″, 8″ and 12″ in c-cut, a-cut, m-cut, or r-cut orientations, comprise possible starting crystalline materials.

The above represent some of the main crystallographic orientations of single crystal sapphire. For example, a c-cut crystal means that the large face is parallel (cut) along the c plane where the c-axis is perpendicular to the crystal surface. Off-axis cuts are possible and are usually characterized by a miscut angle from the major crystallographic axes. Accordingly, certain embodiments may comprise material having an orientation corresponding predominantly, but not exactly, to a cut orientation of a major crystallographic axis. Since beam-induced cleaving is a surface referenced method, cleaves will occur at a predefined depth parallel to the crystal face.

Incorporated by reference herein for all purposes, is Azhdari and Nemat-Nasser, “Experimental and computational study of fracturing in an anisotropic brittle solid”, Mechanics of Materials, Vol. 28, pp. 247-262 (1998). That paper discusses the structure of single crystal sapphire, including the orientations of various possible cleave planes of that bulk material.

Since 1997, Silicon Genesis Corp. (“SiGen”) has reported the development and use of cleaving processes utilizing implanted particles (including but not limited to protons). Incorporated by reference herein for all purposes, is U.S. Pat. No. 6,013,563 describing various aspects of certain cleaving processes. Embodiments described herein may share one or more characteristics described in that patent.

According to particular embodiments, a surface of a bulk starting material may be subjected to implantation with accelerated particles, to form a cleave region. In certain embodiments, this cleave region may lie at a depth of between about 10-20 μm underneath the surface of the bulk material. Formation of a cleave region depends upon such factors as the target material, the crystal orientation of the target material, the nature of the implanted particle(s), the dose, energy, and temperature of implantation, and the direction of implantation. Such implantation is discussed further in detail below, and may share one or more characteristics described in detail in connection with the following patent applications, all of which are incorporated by reference in their entireties herein: U.S. patent application Ser. No. 12/789,361; U.S. patent application Ser. No. 12/730,113; U.S. patent application Ser. No. 11/935,197; U.S. patent application Ser. No. 11/936,582; U.S. patent application Ser. No. 12/019,886; U.S. patent application Ser. No. 12/244,687; U.S. patent application Ser. No. 11/685,686; U.S. patent application Ser. No. 11/784,524; U.S. patent application Ser. No. 11/852,088.

Since 2008, SiGen has reported the development and use of a new beam-induced cleave process using a high-energy and high fluence proton beam and a proprietary cleaving system technology to initiate and guide a fracture for efficient kerf-free wafering of a thickness of crystalline material. Incorporated by reference herein for all purposes are the following U.S. Patent Publications describing aspects of certain cleaving processes: 2008/0206962; 2008/0128641; 2009/0277314; and 2010/0055874.

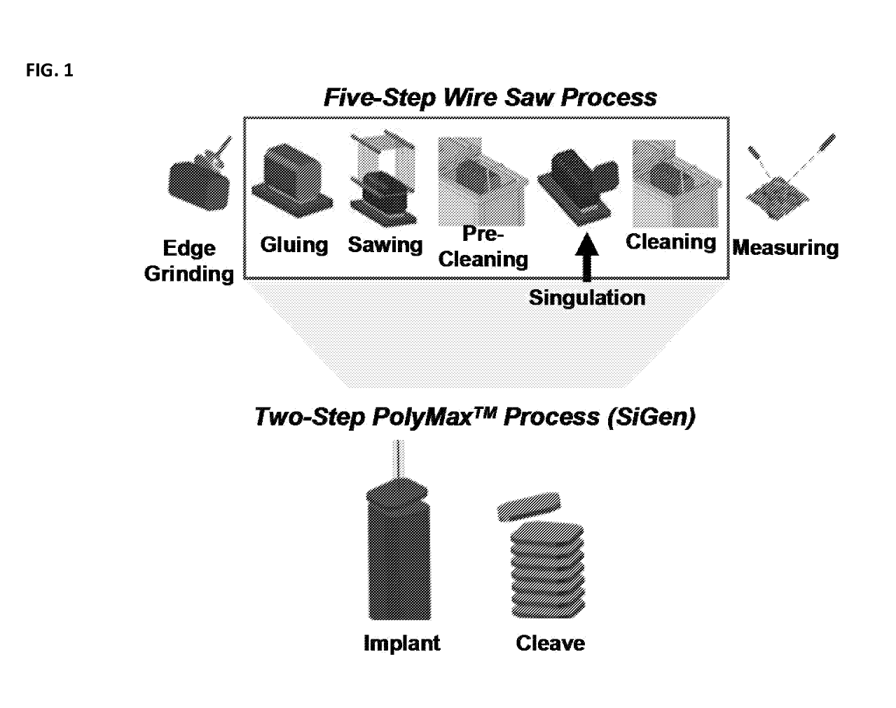

Announced for the preparation of single-crystal silicon solar PV wafers, the process is called PolyMax™ using Direct Film Transfer (DFT) technology. The kerf-free, dry wafering process uses a 2-step implant-cleave method shown in FIG. 1 where high-energy proton irradiation first forms a cleave plane followed by advanced controlled cleaving to initiate and propagate a fracture plane in a controlled manner along the cleave plane to release a large-area wafer from a shaped ingot.

The ion beam-induced cleaving process has been used to demonstrate the slicing of full mono-crystalline silicon wafers ranging in thickness from 20 μm to 150 μm with excellent material quality (electrical, Total Thickness Variation (TTV), surface roughness, mechanical strength).

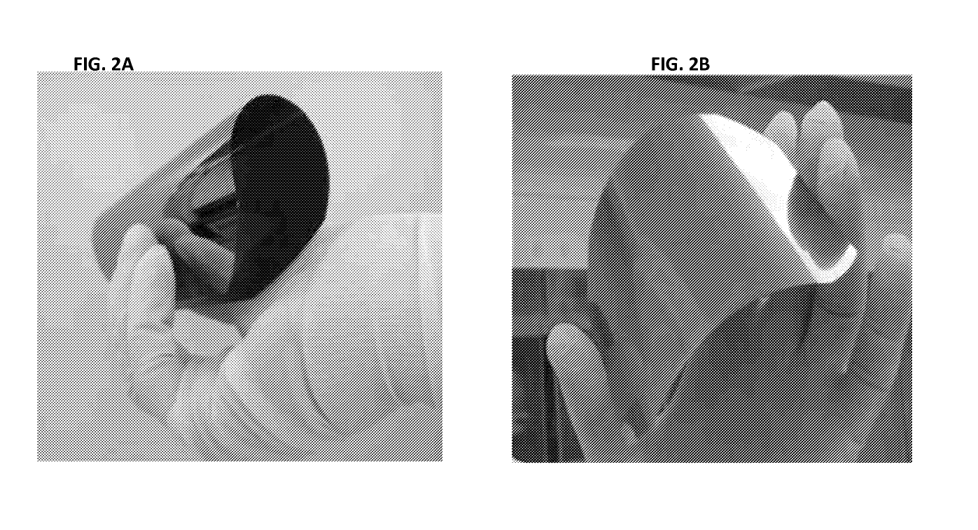

FIGS. 2A-2B show 125 mm pseudo-square substrates made using the PolyMax™ process. The substrate of FIG. 2A has a thickness of 20 μm. The substrate of FIG. 2B has a thickness of 50 μm.

A system according to certain embodiments may allow the cleaving of 20 μm to 150 μm thick silicon wafers directly from CZ boules of silicon. However, this technology may also be adapted to kerfless wafering of other types of crystalline bulk materials, including but not limited to sapphire, Group III/V materials such as GaN, SiC, and others.

The higher density of sapphire (3.98 g/cm³) versus that of single crystal silicon (2.3 g/cm³) will lower the cleave depth at a given energy of implanted particle. If adapted to work with sapphire, a DFT system may cleave sapphire wafers between 5-100 μm in thickness. Examples of sapphire layer thicknesses cleaved according to various embodiments include but are not limited to 5 μm, 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, or 100 μm. Greater thicknesses of cleaved materials are possible, depending in part upon the energy to which the implanted particle is able to be accelerated and its stopping range in the target material.

Such a thin layer thickness could be used directly as a lower cost alternative substrate to a 400-600 μm sapphire High-Brightness Light-Emitting Diode (HB-LED) starting substrate. The kerf-free nature of the process in combination with lower sapphire material utilization could substantially lower one of the highest costs in GaN LED manufacturing. The same principle could be applied to SiC and other starting growth substrates.

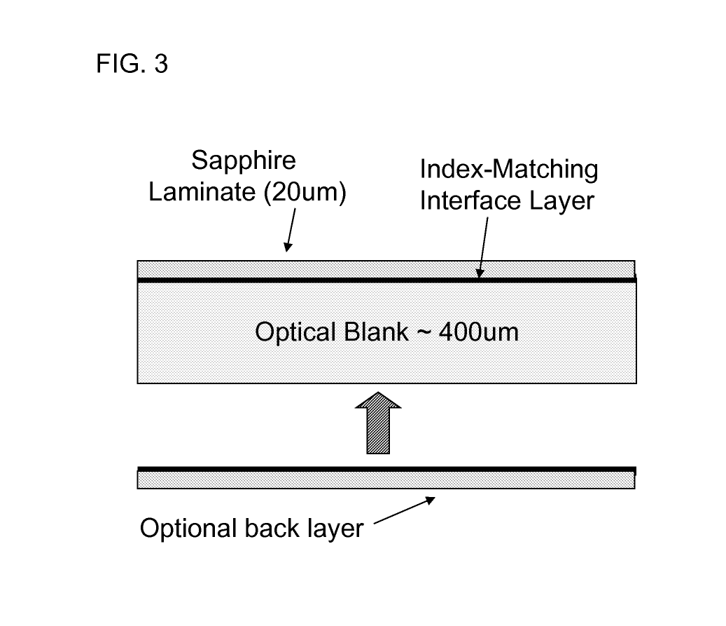

In order to create a material having a greater thickness (e.g. 400-600 μm), a laminated structure may be adopted. An embodiment of a proposed laminated structure is shown in FIG. 3. Depending on the particular application, one or two sapphire laminates may be affixed onto an optical blank of approximately 400 μm in thickness.

An index-matching interface layer may be used to affix the laminates onto the blank. The final choice of the optical blank and index-matching interface layer materials can be dependent on the desired use.

For example, depending on the application's temperature range, the interface layer can be an index-matching fluid, epoxy, or some other material. Thus a quartz blank used in a wide temperature range application, may employ an optical index-matched fluid instead of an epoxy. This would allow for differential thermal expansion mismatch, and reduce the possibility of stress-induced fractures. For the quartz example, its large differential thermal expansion mismatch with sapphire would necessitate careful stress engineering and possibly the use of an index matching fluid. Their respective index of refraction would correspond to an internal reflection at the quartz/sapphire interface of less than 1%. If this level is unacceptable for the application, a quarter-wave or dielectric stack matching coating in combination with the index-matching interface layer could be applied to reduce internal reflections to a desirable level.

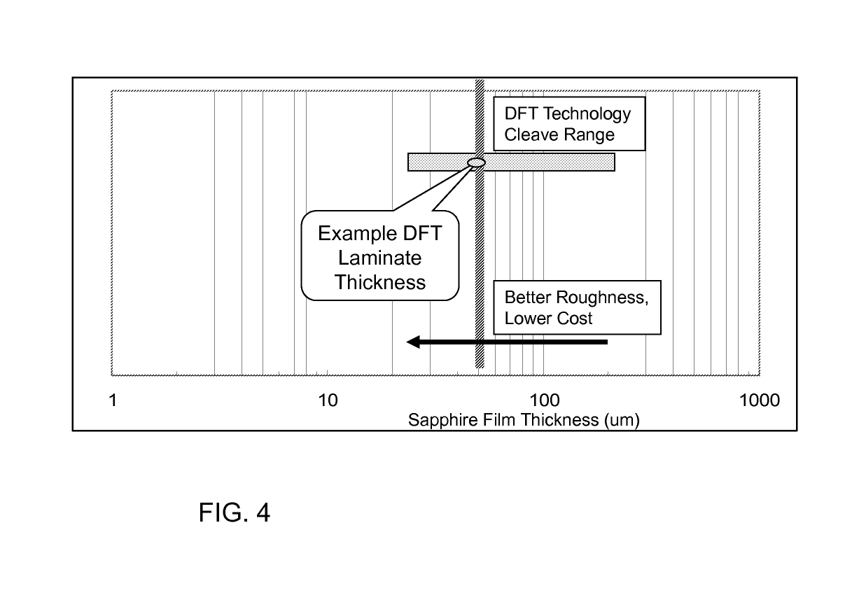

If a laminated structure is used, FIG. 4 shows cleaving of thinner wafers of about 20 μm in thickness using a lower energy and more compact implanter configuration. The chosen energy is about 1.75 MeV to release approximately 20 μm of material. An operating energy of about 1.75 MeV would allow laminates of 20 μm thickness to be released with little loss of material.

Use of a laminate window according to an embodiment may offer one or more possible benefits versus a solid monolithic sapphire layer. Examples of such possible benefits are provided below.

A laminate window may require much smaller (about 30× less) utilization of relatively expensive sapphire material per window.

The cost of kerf-free wafering is lower on an area basis, and may be especially attractive with larger sapphire core diameters (6″ and up).

The TTV of the laminate may be on the order of about +/−0.02 μm. By contrast, a solid sapphire window formed by conventional wiresawing can exhibit a TTV greater than the proposed laminate thickness (>+/−20 μm)

The as-cleaved roughness is expected to be approximately 6 nm Ra. The smoothness of this material would not demand substantial additional polishing steps.

The as-cleaved layer can transmit wavelengths from 150 to 6000 nm and has refractive index of 1.7 to 1.8, and reflection loss of 8-12% at 3 microns.

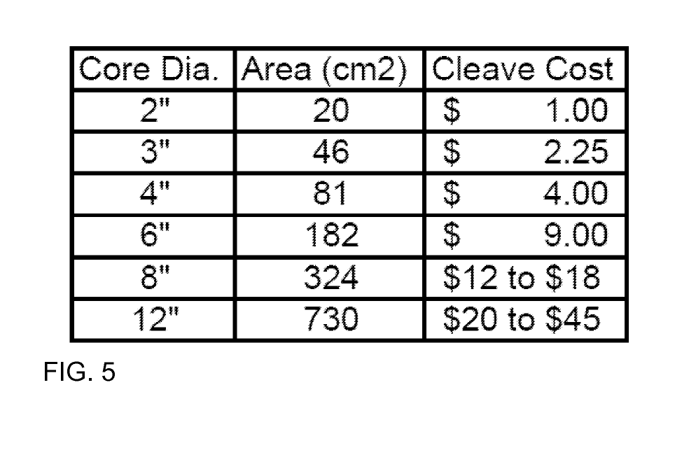

Cost savings may be a function of the area of cleaving, and is estimated in the table of FIG. 5. Using modified implant systems developed for cleaving silicon substrates for the solar photovoltaic industry, costs are estimated to be $0.05/cm², but can be modified by the packing density of the cores within the scanned implant area of approximately 1 m×1 m.

The 8″ and 12″ cost range given in FIG. 5 is due to the lower packing density of the large round cores within the implant scan area. The lower number is for a squared core shape. Even with rounded cores, the lower number may be approached using a patterned beam scan that avoids the inter-core gaps. Using a 6″ core form factor as an example, the cost comparison between wiresaw and DFT windows can be estimated.

The table of FIG. 5 reflects a number of assumptions, including a core cost of $150/mm, a wiresaw window core use of 600 μm, and a DFT window core use (one side) of 20 μm. Wiresaw cost estimation was based upon: window cost=material cost ($90)+wiresaw cost+rough/fine/touch polish cost. The wiresaw cost would include not only the actual sawing but the various clean and singulation steps.

The DFT cost estimation was based upon: window cost=material cost ($3)+cleave cost ($9)+touch polish cost+optical blank cost+index-matching interface layer cost. This illustrates the substantial cost reduction potential of the technology.

While the above description has focused upon a single crystal layer of material having a planar shape, this is not required. Alternative embodiments could form a single crystal layer having other than a planar shape. For example, the single crystal layer could be curved in order to match a profile of a lens such as a cylindrical or spherical lens.

The various physical properties of sapphire, as contrasted with other materials, may involve the use of one or more techniques. For example, sapphire exhibits a low emissivity at temperatures below about 800° C. This makes detecting the temperature of the bulk material during processing steps such as implant and/or cleaving, difficult at lower temperatures.

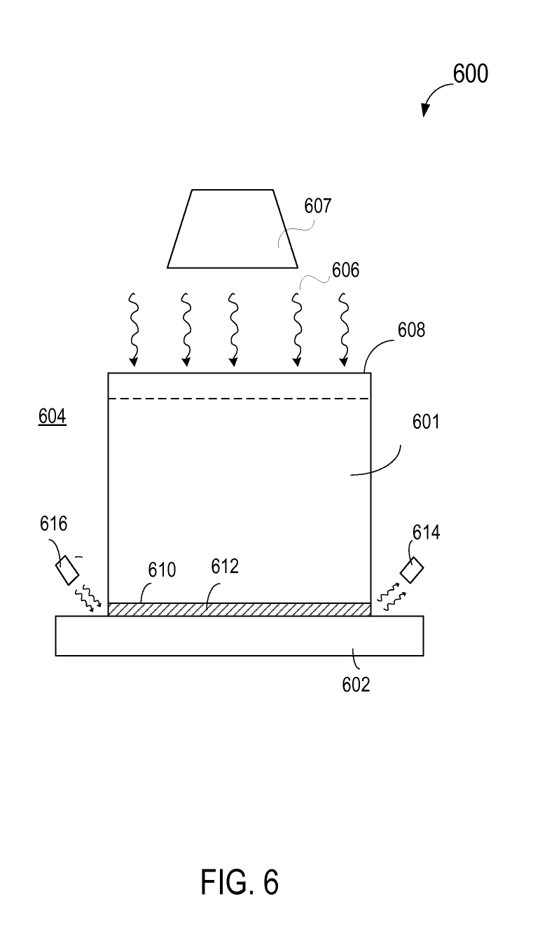

Accordingly, FIG. 6 shows a simplified view of an embodiment of a rig 600 for processing sapphire. In particular, the bulk sapphire core 601 is supported by process chuck 602 within vacuum chamber 604. Beam 606 of accelerated particles from source 607 is implanted into the top surface 608 of the sapphire core.

On its bottom surface 610, the core bears a coating 612 comprising a material whose emissivity renders it suitable for thermal measurement over the full range of temperatures expected to be experienced during processing. Examples of such coatings include but are not limited to metal or carbon. Accordingly the process rig also includes a thermal detector 614 in communication with the coating.

The emissive coating 612 may perform functions other than temperature detection. For example, the coating may allow thermal control over the bulk material by radiative cooling.

Indeed, such radiative cooling by a coating may offer a practical cooling mechanism available to a sapphire core undergoing processing (such as particle implantation) at temperatures of about 650-850° C. Specifically as implantation is performed in a vacuum environment, cooling by convection is not an option. Moreover, the chuck may be selected to not have an appreciable cooling path for the sapphire core undergoing implantation, thereby substantially reducing or eliminating entirely the possibility of cooling the sapphire core via conduction. If the implant heat flux is matched to the coating's radiation cooling flux when the implant surface reaches the desired implant temperature, the coating can serve to control the implant at high temperatures without additional complex and costly cooling methods.

U.S. Pat. No. 6,458,723 titled “High Temperature Implant Apparatus”, is hereby incorporated by reference in its entirety for all purposes. One or more concepts disclosed in that patent may find use according to various embodiments here. It is noted that depending upon the particular material and the specific conditions under which implantation occurs, the temperature could lie in a range between about 50-900° C. For implantation of sapphire, the temperature range at implantation may range between about 650-850° C.

Still another function that may be performed by a coating due to its absorptive nature for heating the sapphire for annealing and cleaving. Specifically, once particles have been introduced by implantation, additional energ(ies) may need to be applied in order to permit initiation and/or propagation of the cleaving process. In certain embodiments, such energ(ies) may be provided in the form of luminance, with the coating serving to absorb the applied light and convert it into the thermal energy responsible for cleave initiation and/or propagation.

Accordingly, the process rig may further comprise a source 616 of electromagnetic radiation, which may be applied to the coating. Examples of such sources include but are not limited to lamps such as QTH (Quartz Tungsten Halogen) flashlamps and lasers.

It is further noted that certain electrical properties of sapphire may dictate its being subjected to implantation at elevated temperatures. Specifically, the electric field breakdown strength of sapphire at room temperature may be insufficient to withstand the high buildup of local electrical fields resulting from the implantation of charged particles, without exceeding a breakdown electric field strength (E_{BD}). However it is known that the resistivity (p) of sapphire decreases with increasing temperature (approximately 1×10¹⁶ Ω-cm at room temperature to 1×10⁶ Ω-cm at 1000° C.), and thus material breakdown can be avoided by increasing the temperature until the following equation is satisfied:

ρ(T)<E_{BD}/Iₐ

where Iₐ is the current per area being implanted in amperes/cm².

Given an estimated sapphire E_{BD} of about 4.8×10⁵ V/cm and an implant flux of 2.5 μA/cm², the maximum resistivity permitted to avoid material breakdown is about 2×10¹¹ Ω-cm. This resistivity occurs at about 500° C., therefore it is expected that increasing the temperature of a sapphire core above 500° C. prior to commencing implantation may be useful to avoid breakdown of the material. Accordingly, it may be desirable to employ a coating for the purpose of radiative heating of the sapphire core prior to its implantation with charged particles for this purpose.

Certain thermo-mechanical properties of a sapphire core may enhance its ability to be cleaved into individual layers according to various embodiments. Specifically, within its expected implantation temperature range (e.g. 650-850° C.), sapphire also exhibits a relatively high coefficient of thermal expansion, together with a relatively low degree of thermal conductivity. Furthermore, the application of accelerated particles for implantation may occur as a scanned beam, with a relative dwell time at any point of as little as 80 μs.

The resulting rapid pulse heating of sapphire is contained near surface areas of the core receiving the beam by the sapphire's low thermal conductivity. Accordingly, at temperatures of about 800° C., e.g., 775° C. to 825° C., regions of a few tens of microns proximate to the implanted surface of the core will be expected to undergo repeated thermal expansion, followed by rapid contraction as excess heat is removed by conductive cooling to the rest of the sapphire bulk. The resulting stresses in the surface regions of the implanted core may serve to provide energy for cleave initiation and/or propagation.

For example, using a 2 cm beam of 15 kW power scanned over a 50 cm×50 cm area with a beam velocity of 250 m/s, a thickness of about 30 μm beneath the implant surface undergoes a temperature rise of about 70° C. within 80 μs. This is followed by cooling to bulk temperature within a few milliseconds. During that brief time, surface compressive shear stresses exceeding 150-200 MPa are developed that can augment the cleave plane chemical stresses to help prepare the implanted layer for cleaving.

Although the above description has been primarily in terms of a sapphire bulk material, other substrates may also be used. For example, the substrate can be almost any monocrystalline, polycrystalline, or even amorphous type substrate. One example of a suitable material is silicon carbide (SiC). Additionally, the substrate can be made of III/V materials such as gallium arsenide (GaAs), gallium nitride (GaN), and others. A multi-layered substrate can also be used according to various embodiments. The multi-layered substrate includes a silicon-on-insulator substrate, a variety of sandwiched layers on a semiconductor substrate, and numerous other types of substrates.

Embodiments may employ pulsed energy in addition to, or in place of, scanned energy, to initiate or propagate a controlled cleaving action. The pulse can be replaced or supplemented by energy that is scanned across a selected region of the substrate to initiate the controlled cleaving action. Energy can also be scanned across selected regions of the substrate to sustain or maintain the controlled cleaving action. One of ordinary skill in the art would easily recognize a variety of alternatives, modifications, and variations, which can be used according to the present invention.

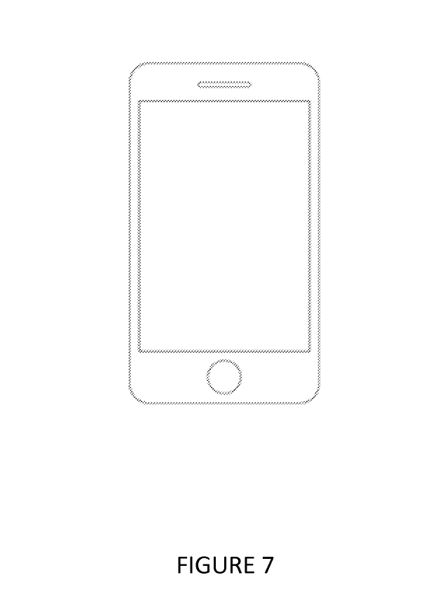

FIG. 7 is a simplified diagram illustrating a smart phone according to an embodiment of the present invention. As shown, the smart phone includes a housing, display, and interface device, which may include a button, microphone, or touch screen. Preferably, the phone has a high resolution camera device, which can be used in various modes. An example of a smart phone can be an iPhone from Apple Computer of Cupertino Calif. Alternatively, the smart phone can be a Galaxy from Samsung or others.

In some embodiments, the display has a screen, and a cover of the display screen includes a cleaved single crystal sapphire layer having a thickness of between about 5 μm to about 100 nm. The cleaved single crystal sapphire layer may be formed using the cleaving methods described above. The various features of the smart phone are described here as an example. It is understood that these features can be implemented in other electronic devices, for example, a tablet device in some embodiments of the invention.

In an example, the smart phone includes the following features (which are found in an iPhone 4 from Apple Computer, although there can be variations), see www.apple.com.

“GSM model: UMTS/HSDPA/HSUPA (850, 900, 1900, 2100 MHz);

### GSM/EDGE (850, 900, 1800, 1900 MHz);

CDMA model: CDMA EV-DO Rev. A (800, 1900 MHz);
802.11b/g/n Wi-Fi (802.11n 2.4 GHz only);
Bluetooth 2.1+EDR wireless technology;

### Assisted GPS;

Digital compass;

### Wi-Fi;

### Cellular;

Retina display;
3.5-inch (diagonal) widescreen Multi-Touch display;
800:1 contrast ratio (typical);
500 cd/m2 max brightness (typical);
Fingerprint-resistant oleophobic coating on front and back;
Support for display of multiple languages and characters simultaneously;
5-megapixel iSight camera;
Video recording, HD (720p) up to 30 frames per second with audio;
VGA-quality photos and video at up to 30 frames per second with the front camera;
Tap to focus video or still images;
LED flash;
Photo and video geotagging;
Built-in rechargeable lithium-ion battery;
Charging via USB to computer system or power adapter;
Talk time: Up to 7 hours on 3G, up to 14 hours on 2G (GSM);
Standby time: Up to 300 hours;
Internet use: Up to 6 hours on 3G, up to 10 hours on Wi-Fi;
Video playback: Up to 10 hours;
Audio playback: Up to 40 hours;
Frequency response: 20 Hz to 20,000 Hz;
Audio formats supported: AAC (8 to 320 Kbps), Protected AAC (from iTunes Store), HE-AAC, MP3 (8 to 320 Kbps), MP3 VBR, Audible (formats 2, 3, 4, Audible Enhanced Audio, AAX, and AAX+), Apple Lossless, AIFF, and WAV;
User-configurable maximum volume limit;
Video out support at up to 720p with Apple Digital AV Adapter or Apple VGA Adapter; 576p and 480p with Apple Component AV Cable; 576i and 480i with Apple Composite AV Cable (cables sold separately);
Video formats supported: H.264 video up to 720p, 30 frames per second, Main Profile Level 3.1 with AAC-LC audio up to 160 Kbps, 48 kHz, stereo audio in .m4v, .mp4, and .mov file formats; MPEG-4 video up to 2.5 Mbps, 640 by 480 pixels, 30 frames per second, Simple Profile with AAC-LC audio up to 160 Kbps per channel, 48 kHz, stereo audio in .m4v, .mp4, and .mov file formats; Motion JPEG (M-JPEG) up to 35 Mbps, 1280 by 720 pixels, 30 frames per second, audio in ulaw, PCM stereo audio in .avi file format;
Three-axis gyro;

### Accelerometer;

Proximity sensor;
Ambient light sensor.”

An exemplary electronic device may be a portable electronic device, such as a media player, a cellular phone, a personal data organizer, or the like. Indeed, in such embodiments, a portable electronic device may include a combination of the functionalities of such devices. In addition, the electronic device may allow a user to connect to and communicate through the Internet or through other networks, such as local or wide area networks. For example, the portable electronic device may allow a user to access the internet and to communicate using e-mail, text messaging, instant messaging, or using other forms of electronic communication. By way of example, the electronic device may be a model of an iPod having a display screen or an iPhone available from Apple Inc.

In certain embodiments, the device may be powered by one or more rechargeable and/or replaceable batteries. Such embodiments may be highly portable, allowing a user to carry the electronic device while traveling, working, exercising, and so forth. In this manner, and depending on the functionalities provided by the electronic device, a user may listen to music, play games or video, record video or take pictures, place and receive telephone calls, communicate with others, control other devices (e.g., via remote control and/or Bluetooth functionality), and so forth while moving freely with the device. In addition, device may be sized such that it fits relatively easily into a pocket or a hand of the user. While certain embodiments of the present invention are described with respect to a portable electronic device, it should be noted that the presently disclosed techniques may be applicable to a wide array of other, less portable, electronic devices and systems that are configured to render graphical data, such as a desktop computer.

In the presently illustrated embodiment, the exemplary device includes an enclosure or housing, a display, user input structures, and input/output connectors. The enclosure may be formed from plastic, metal, composite materials, or other suitable materials, or any combination thereof. The enclosure may protect the interior components of the electronic device from physical damage, and may also shield the interior components from electromagnetic interference (EMI).

The display may be a liquid crystal display (LCD), a light emitting diode (LED) based display, an organic light emitting diode (OLED) based display, or some other suitable display. In accordance with certain embodiments of the present invention, the display may display a user interface and various other images, such as logos, avatars, photos, album art, and the like. Additionally, in one embodiment, the display may include a touch screen through which a user may interact with the user interface. The display may also include various function and/or system indicators to provide feedback to a user, such as power status, call status, memory status, or the like. These indicators may be incorporated into the user interface displayed on the display.

In one embodiment, one or more of the user input structures are configured to control the device, such as by controlling a mode of operation, an output level, an output type, etc. For instance, the user input structures may include a button to turn the device on or off. Further the user input structures may allow a user to interact with the user interface on the display. Embodiments of the portable electronic device may include any number of user input structures, including buttons, switches, a control pad, a scroll wheel, or any other suitable input structures. The user input structures may work with the user interface displayed on the device to control functions of the device and/or any interfaces or devices connected to or used by the device. For example, the user input structures may allow a user to navigate a displayed user interface or to return such a displayed user interface to a default or home screen.

The exemplary device may also include various input and output ports to allow connection of additional devices. For example, a port may be a headphone jack that provides for the connection of headphones. Additionally, a port may have both input/output capabilities to provide for connection of a headset (e.g., a headphone and microphone combination). Embodiments of the present invention may include any number of input and/or output ports, such as headphone and headset jacks, universal serial bus (USB) ports, IEEE-1394 ports, and AC and/or DC power connectors. Further, the device may use the input and output ports to connect to and send or receive data with any other device, such as other portable electronic devices, personal computers, printers, or the like. For example, in one embodiment, the device may connect to a personal computer via an IEEE-1394 connection to send and receive data files, such as media files. Further details of the device can be found in U.S. Pat. No. 8,294,730, assigned to Apple, Inc.

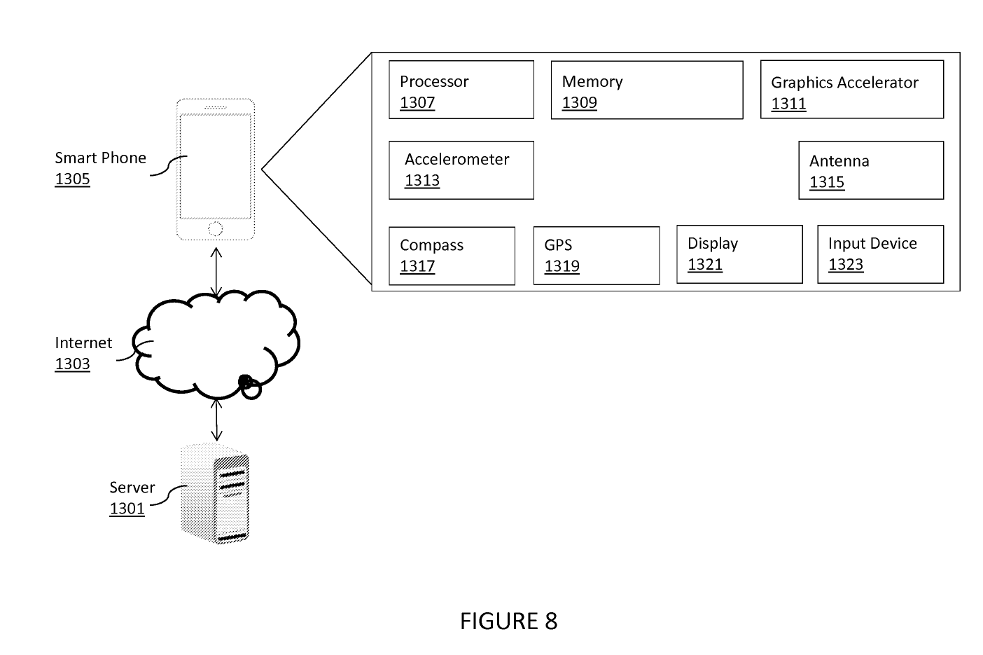

FIG. 8 is a simplified system diagram with a smart phone according to an embodiment of the present invention. A server 1301 is in electronic communication with a handheld electronic device 1305, such as a smart phone, having functional components such as a processor 1307, memory 1309, graphics accelerator 1311, accelerometer 1313, communications interface 1325, compass 1317, GPS 1319, display 1321, and input device 1323. Each device is not limited to the illustrated components. The components may be hardware, software or a combination of both.

In some examples, instructions are input to the handheld electronic device 1305 through an input device 1323 that instructs the processor 1307 to execute functions in an electronic imaging application. One potential instruction can be to generate a wireframe of a captured image of a portion of a human user. In that case the processor 1307 instructs the communications interface 1325 to communicate with the server 1301 and transfer human wireframe or image data. The data transferred by the communications interface 1325 and either processed by the processor 1307 immediately after image capture or stored in memory 1309 for later use, or both. The processor 1307 also receives information regarding the attributes of display 1321, and can calculate the orientation of the device, or e.g., using information from an accelerometer 1313 and/or other external data such as compass headings from a compass 1317, or GPS location from a GPS chip, and the processor then uses the information to determine an orientation in which to display the image depending upon the example.

The captured image can be drawn by the processor 1307, by a graphics accelerator 1311, or by a combination of the two. In some embodiments, the processor can be the graphics accelerator. The image can be first drawn in memory 1309 or, if available, memory directly associated with the graphics accelerator 1311. The methods described herein can be implemented by the processor 1307, the graphics accelerator 13211, or a combination of the two to create the image and related wireframe. Once the image or wireframe is drawn in memory, it can be displayed on the display 1321.

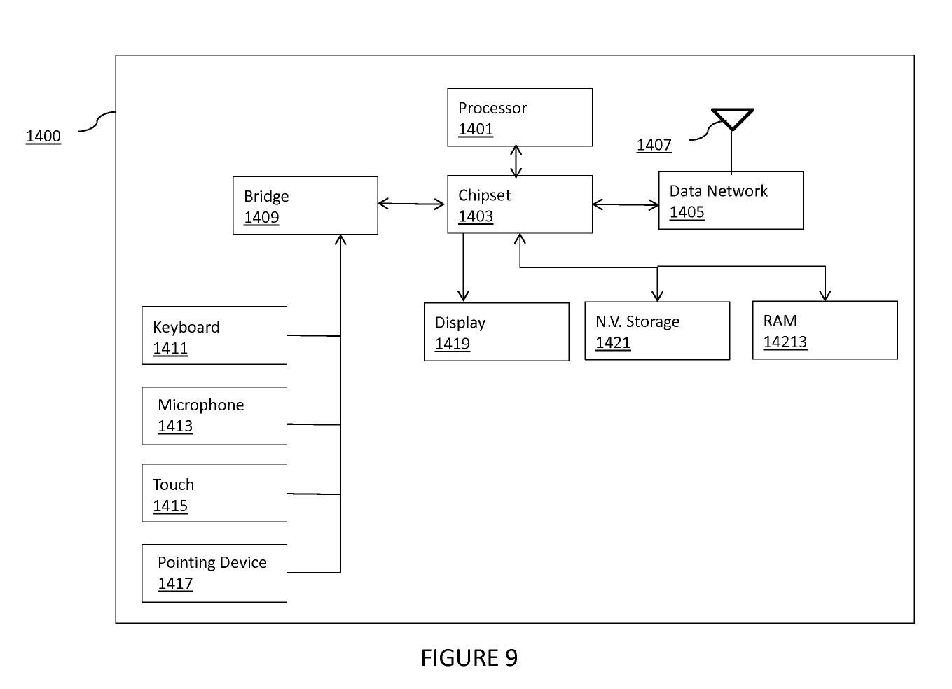

FIG. 9 is a simplified diagram of a smart phone system diagram according to an embodiment of the present invention. Smart phone system 1400 is an example of computer hardware, software, and firmware that can be used to implement disclosures above. System 1400 includes a processor 1401, which is representative of any number of physically and/or logically distinct resources capable of executing software, firmware, and hardware configured to perform identified computations. Processor 1401 communicates with a chipset 1403 that can control input to and output from processor 1401. In this example, chipset 1403 outputs information to display 1419 and can read and write information to non-volatile storage 1421, which can include magnetic media and solid state media, for example. Chipset 1403 also can read data from and write data to RAM 1423. A bridge 1409 for interfacing with a variety of user interface components can be provided for interfacing with chipset 1403. Such user interface components can include a keyboard 1411, a microphone 1413, touch-detection-and-processing circuitry 1415, a pointing device such as a mouse 1417, and so on. In general, inputs to system 1400 can come from any of a variety of sources, machine-generated and/or human-generated sources.

Chipset 1403 also can interface with one or more data network interfaces 1405 that can have different physical interfaces 1407, such as an antenna. Such data network interfaces can include interfaces for wired and wireless local area networks, for broadband wireless networks, as well as personal area networks. Some applications of the methods for generating and displaying and using the GUI disclosed herein can include receiving data over physical interface 1477 or be generated by the machine itself by processor 1401 analyzing data stored in memory 1421 or 1423. Further, the machine can receive inputs from a user via devices keyboard 1411, microphone 1413, touch device 1415, and pointing device 1417 and execute appropriate functions, such as browsing functions by interpreting these inputs using processor 1401.

As used herein, the term “first” “second” “third” or “nth” does not necessary imply order and should be interpreted in accordance with ordinary meaning. These terms should not necessarily be used for order or for logic, and may refer to two separate terms or can be combined into a single term. Of course, there can be other variations, modifications, and alternatives.

While the above is a full description of the specific embodiments, various modifications, alternative constructions and equivalents may be used. Although the above has been described using a selected sequence of steps, any combination of any elements of steps described as well as others may be used. Additionally, certain steps may be combined and/or eliminated depending upon the embodiment. Furthermore, the particles of hydrogen can be replaced using co-implantation of helium and hydrogen ions or deuterium and hydrogen ions to allow for formation of the cleave plane with a modified dose and/or cleaving properties according to alternative embodiments. Still further, the particles can be introduced by a diffusion process rather than an implantation process. Of course there can be other variations, modifications, and alternatives. Therefore, the above description and illustrations should not be taken as limiting the scope of the present invention which is defined by the appended claims.

Exemplary Implementations:

29. A biometric recognition device, comprising an optical surface; and a first cleaved single crystal sapphire layer having a thickness of between about 5 μm to about 100 μm, wherein the optical surface is defined by the first cleaved single crystal sapphire layer.

30. The device of 29, further comprising a laminate structure including the first cleaved single crystal sapphire layer, an optical blank, and an index matching material positioned between the first cleaved single crystal sapphire layer and the optical blank.

31. The device of 30, wherein the index matching material comprises an index-matching fluid.

32. The device of 30, further comprising: a second cleaved single crystal sapphire layer positioned on an opposite side of the optical blank from the first cleaved single crystal sapphire layer; and a second index matching material positioned between the optical blank and the second cleaved single crystal sapphire layer.

33. The device of 29, wherein the first cleaved single crystal sapphire layer comprises c-cut oriented material.

34. The device of 29, wherein the first cleaved single crystal sapphire layer comprises a-cut oriented material.

35. The device of 29, wherein the first cleaved single crystal sapphire layer comprises r-cut oriented material.

36. The device of 29, wherein the first cleaved single crystal sapphire layer is characterized by a miscut angle from a major crystallographic axis.

What is claimed is:

1. An electronic device comprising:
a housing structure;
a display screen configured within the housing structure;
one or more processors provided within the housing structure;
a memory device coupled to the one or more processors;
one or more input devices; and
a cover configured for the display screen, the cover comprising a first cleaved single crystal sapphire layer having a thickness of between about 5 μm to about 100 μm.

2. The device of claim 1, wherein the electronic device is a mobile phone or a tablet device; and wherein the first cleaved single crystal sapphire layer is obtained from a thickness of sapphire substrate by a controlled cleaving process.

3. The device of claim 1, further comprising a biometric recognition device including an optical surface defined by the first cleaved single crystal sapphire layer.

4. The device of claim 1, wherein the cover of the display screen further comprises:
an optical blank; and
an index matching material positioned between the first cleaved single crystal sapphire layer and the optical blank.

5. The device of claim 4, wherein the index matching material comprises an index-matching fluid or solid.

6. The device of claim 4, further comprising:
a second cleaved single crystal sapphire layer positioned on an opposite side of the optical blank from the first cleaved single crystal sapphire layer; and
a second index matching material positioned between the optical blank and the second cleaved single crystal sapphire layer.

7. The device of claim 1, wherein the first cleaved single crystal sapphire layer comprises c-cut oriented material.

8. The device of claim 1, wherein the first cleaved single crystal sapphire layer comprises a-cut oriented material.

9. The device of claim 1, wherein the first cleaved single crystal sapphire layer comprises r-cut oriented material.

10. The device of claim 1, wherein the first cleaved single crystal sapphire layer is characterized by a miscut angle from a major crystallographic axis.

11. The device of claim 1, wherein the first cleaved single crystal sapphire layer has a surface roughness of 6 nm Ra or less.

12. The device of claim 1, wherein the first cleaved single crystal sapphire layer is configured to transmit wavelengths from 150 to 6000 nm.

13. A method for manufacturing an electronic device the method comprising:
providing a bulk single crystal sapphire material;
positioning the bulk single crystal sapphire material to a particle accelerator;
accelerating protons from the particle accelerator into the surface of the bulk single crystal sapphire material to form a sub-surface cleave region;
applying energy to a portion of the bulk single crystal sapphire material to cause controlled cleaving of the bulk single crystal sapphire material along the sub-surface cleave region to form a cleaved single crystal sapphire layer having a thickness of between about 5 μm to about 100 μm;
transferring the cleaved single crystal sapphire layer; and
incorporating the cleaved single crystal sapphire layer in a cover of the electronic device.

14. The method of claim 13, wherein the electronic device comprises a mobile phone or a tablet device.

15. The method of claim 13, wherein the cleaved single crystal sapphire layer is part of a display screen.

16. The method of claim 13, wherein cleaved single crystal sapphire layer is part of an optical surface of biometric recognition device.

17. The method of claim 13, further comprising:
providing the cleaved single crystal sapphire layer;
providing an optical blank; and
providing an index matching material positioned between the cleaved single crystal sapphire layer and the optical blank to form an optical laminate,
wherein the cleaved single crystal sapphire layer is affixed onto the optical blank.

18. The method of claim 17, further comprising incorporating the optical laminate in a display screen; wherein the cleaved single crystal sapphire layer is provided by a cleaving process to form a free standing film of the cleaved single crystal sapphire layer, a bonding and a cleaving process such that the single crystal sapphire material is affixed to the optical blank and subjected to the cleaving process to release the cleaved single crystal sapphire layer onto the optical blank, or a bonding and a cleaving process using an intermediary substrate and a release material to temporarily hold the cleaved single crystal sapphire layer before the cleaved single crystal sapphire layer is affixed onto the optical blank.

19. The method of claim 17, further comprising incorporating the optical laminate in a biometric recognition device.

20. The method of claim 13, wherein the cleaved single crystal sapphire layer comprises c-cut oriented material.

21. The method of claim 13, wherein the cleaved single crystal sapphire layer is selected from at least one of an a-cut oriented material, an r-cut oriented material, or a c-cut oriented material.

22. The method of claim 13, wherein the cleaved single crystal sapphire layer is characterized by a miscut angle from a major crystallographic axis.

23. The method of claim 13, wherein the cleaved single crystal sapphire layer has a surface roughness of 6 nm Ra or less.

24. The method of claim 13, wherein the cleaved single crystal sapphire layer is configured to transmit wavelengths from 150 to 6000 nm.

25. The method of claim 13, wherein the protons are accelerated into the surface of the bulk single crystal sapphire material while a temperature of the bulk single crystal sapphire material is increased.

26. The method of claim 25, wherein the temperature is increased until the following equation is satisfied:
ρ(T)<EBD/Iₐ
where Iₐ is the current per area being implanted in amperes/cm².

27. The method of claim 13, wherein the energy applied to the portion of the bulk single crystal sapphire material to cause controlled cleaving of the bulk single crystal sapphire material is a rapid pulse heating process conducted in a temperature of about 800° C.

28. The device of claim 27, wherein the temperature is between 775° C. to 825° C.

29. A biometric recognition device, comprising
an optical surface; and
a first cleaved single crystal sapphire layer having a thickness of between about 5 μm to about 100 μm,
wherein the optical surface is defined by the first cleaved single crystal sapphire layer.

30. The device of claim 29, further comprising a laminate structure including the first cleaved single crystal sapphire layer, an optical blank, and an index matching material positioned between the first cleaved single crystal sapphire layer and the optical blank.
